(19) United States
(12) Patent Application Publication
(10) Pub. No.: US 2024/0303400 A1
(43) Pub. Date: Sep. 12, 2024

(54) VALIDATION FOR AUTONOMOUS SYSTEMS

(71) Applicant: Waabi Innovation Inc., Toronto (CA)

(72) Inventors: James TU, Toronto (CA); Simon SUO, Toronto (CA); Raquel URTASUN, Toronto (CA)

(73) Assignee: Waabi Innovation Inc., Toronto (CA)

(21) Appl. No.: 18/598,789

(22) Filed: Mar. 7, 2024

Related U.S. Application Data
(60) Provisional application No. 63/450,896, filed on Mar. 8, 2023.

(51) Int. Cl. G06F 30/27; G06F 11/36

(52) U.S. Cl. CPC G06F 30/27; G06F 11/3688

(57) ABSTRACT

A method includes generating a first sample including first raw parameter values of a first modifiable parameters by a probabilistic model and a kernel and executing a first test of a virtual driver of an autonomous system according to the first sample to generate a first evaluation result of multiple evaluation results. The method further includes updating the probabilistic model according to the first evaluation result and training the kernel using the first evaluation result. The method additionally includes generating a second sample including second raw parameter values of the parameters by the probabilistic model and the kernel and executing a second test of a virtual driver of an autonomous system according to the second sample to generate a second evaluation result of the evaluation results. The method further includes presenting the evaluation results.

### CROSS-REFERENCE TO RELATED APPLICATIONS

This application is a non-provisional application of, and thereby claims benefit to U.S. Patent Application Ser. No. 63/450,896 filed on Mar. 8, 2023, which is incorporated herein by reference in its entirety.

### BACKGROUND

Autonomous systems (AVs), such as autonomous vehicles and robots, are used in a variety of applications that involve real world movement. Before deployment, the autonomous system is trained and tested to determine whether the autonomous system is safe to interact in the real world. For example, the autonomous system may be trained and tested to ensure that the autonomous system does not cause and, in fact, mitigates accidents. However, innumerable scenarios exist in the real world. To understand how safe the autonomous system is, a goal is to identify in which of the innumerable scenarios the autonomous system is safe or unsafe with respect to requirements defined by safety experts. Towards the goal, a testing framework may be built that tests the autonomous system. The testing framework should cover the wide range of scenarios in the autonomous system's operational domain.

To cover the wide range of real-world scenarios in a scalable manner, testing frameworks may be built in simulation where the real-world environment is fully controllable and long-tail events can be synthesized. One strategy is to parameterized scenarios. The scenarios describe semantics of the environment (e.g., truck merging from on-ramp). The parameters of the scenario specify low-level characteristics (e.g., velocity of traffic participants) of the scenario. Each parameter configuration then corresponds to a concrete test which can be executed in simulation to determine if the autonomous system complies with functional safety requirements.

However, directly covering all variations in a scenario's parameter space can be infeasible. Continuous parameters imply infinitely many variations, and testing frameworks can only execute a finite number of concrete tests. The number of tests is limited by computation budget. As a result, to cover the parameter space, testing frameworks often convert the raw continuous parameters into discretized parameters. Namely, possible parameter values are grouped into buckets or bins, and then the autonomous vehicle is tested only with a single parameter value from a particular bin. Thus, testing of the autonomous system limits the parameter to the artificial discrete values instead of the raw parameters, which include continuous values.

### SUMMARY

In general, in one aspect, one or more embodiments relate to a method that includes generating a first sample including first raw parameter values of a first modifiable parameters by a probabilistic model and a kernel and executing a first test of a virtual driver of an autonomous system according to the first sample to generate a first evaluation result of multiple evaluation results. The method further includes updating the probabilistic model according to the first evaluation result and training the kernel using the first evaluation result. The method additionally includes generating a second sample including second raw parameter values of the parameters by the probabilistic model and the kernel and executing a second test of a virtual driver of an autonomous system according to the second sample to generate a second evaluation result of the evaluation results. The method further includes presenting the evaluation results.

In general, in one aspect, one or more embodiments relate to a system that includes at least one computer processor. The system also includes a probabilistic model and a kernel executing on the at least one computer processor and configured to perform first operations including generating a first sample including a first raw parameter values of a first modifiable parameters and generating a second sample including a second raw parameter values of the parameters. The system also includes a testing engine executing on the at least one computer processor and configured to perform second operations including executing a first test of a virtual driver of an autonomous system according to the first sample to generate a first evaluation result of multiple evaluation results, and executing a second test of a virtual driver of an autonomous system according to the second sample to generate a second evaluation result of the evaluation results. The system also includes a model training engine executing on the at least one computer processor and configured to perform third operations including updating the probabilistic model according to the first evaluation result and prior to the second sample being generated. The system also includes a kernel training engine executing on the at least one computer processor and configured to perform fourth operations including training the kernel using the first evaluation result. The system also includes an evaluation engine executing on the at least one computer processor and configured to perform fifth operations including presenting the evaluation results.

In general, in one aspect, one or more embodiments relate to a non-transitory computer readable medium including computer readable program code for causing at least one computer processor to perform operations. The operations include generating a first sample including first raw parameter values of a first modifiable parameters by a probabilistic model and a kernel and executing a first test of a virtual driver of an autonomous system according to the first sample to generate a first evaluation result of multiple evaluation results. The operations further include updating the probabilistic model according to the first evaluation result and training the kernel using the first evaluation result. The operations further include generating a second sample including second raw parameter values of the parameters by the probabilistic model and the kernel and executing a second test of a virtual driver of an autonomous system according to the second sample to generate a second evaluation result of the evaluation results. The operations further include presenting the evaluation results.

### BRIEF DESCRIPTION OF DRAWINGS

FIG. 1 shows a diagram of an autonomous training and testing system in accordance with one or more embodiments.

FIG. 2 shows a diagram of an evaluator in accordance with one or more embodiments.

FIG. 3 shows a flowchart for training or testing a virtual driver in accordance with one or more embodiments.

FIG. 4 shows a flowchart for validation of autonomous systems in accordance with one or more embodiments.

FIG. 5 shows an example of validation of an autonomous system in accordance with one or more embodiments.

FIGS. 6A and 6B show a computing system in accordance with one or more embodiments of the invention.

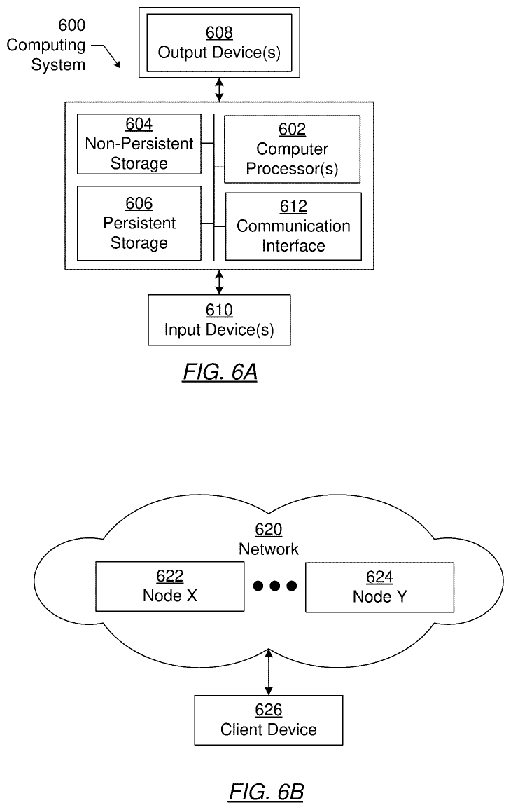

Like elements in the various figures are denoted by like reference numerals for consistency.

### DETAILED DESCRIPTION

In general, one or more embodiments relate to the validation of an autonomous system by testing the autonomous system using the raw parameter values. The testing process is formulated as a sequence of a finite number of tests to estimate the probability of passing or failing across the entire parameter space. Namely, raw parameters that are continuous are sampled from the continuous parameter space rather than discretized and then sampled. Similarly, raw parameters that are categorical may remain with the same set of categories. To perform the testing, a probabilistic model and kernel are used to sample raw parameter values of modifiable parameters and generate a sample for a scenario. Multiple stages of sampling may be performed. In the first stage, the samples are generated randomly as initialization. In the second stage, the samples are generated intelligently based on the probabilistic model and the kernel of the probabilistic model, in a way which prioritizes tests where the system under test is on the boundary of passing and failing.

The virtual driver of the autonomous system is then tested according to the sample to obtain an evaluation result. The evaluation result is used as feedback to update the probabilistic model and the kernel. The updated probabilistic model and kernel may then be used to iteratively perform additional testing. The result of the testing is a performance estimate of the virtual driver under parameters defined in continuous space. The evaluation results may be presented.

The probabilistic model divides the parameter space (i.e., the space defined by the possible parameter values) into a pass region, a fail region, and an uncertain region. By testing samples that are in the uncertain region and/or in the boundary between the pass region and a fail region, a more accurate performance estimate is generated. By sampling from raw parameter values, even parameter values that are close to each other may still be sampled if a small change can cause the pass or fail result to change. One or more embodiments may prioritize samples that are on the boundary of pass and fail or very different from other samples that far evaluated.

As described, embodiments are used to perform the training or testing of an autonomous system. An autonomous system is a self-driving mode of transportation that does not require a human pilot or human driver to move and react to the real-world environment. Rather, the autonomous system includes a virtual driver that is the decision-making portion of the autonomous system. The virtual driver is an artificial intelligence system that learns how to interact in the real world. The autonomous system may be completely autonomous or semi-autonomous. As a mode of transportation, the autonomous system is contained in a housing configured to move through a real-world environment. Examples of autonomous systems include self-driving vehicles (e.g., self-driving trucks and cars), drones, airplanes, robots, etc. The virtual driver is the software that makes decisions and causes the autonomous system to interact with the real-world including moving, signaling, and stopping or maintaining a current state.

The real-world environment is the portion of the real world through which the autonomous system, when trained, is designed to move. Thus, the real-world environment may include interactions with concrete and land, people, animals, other autonomous systems, and human driven systems, construction, and other objects as the autonomous system moves from an origin to a destination. In order to interact with the real-world environment, the autonomous system includes various types of sensors, such as LiDAR sensors amongst other types, which are used to obtain measurements of the real-world environment and cameras that capture images from the real-world environment.

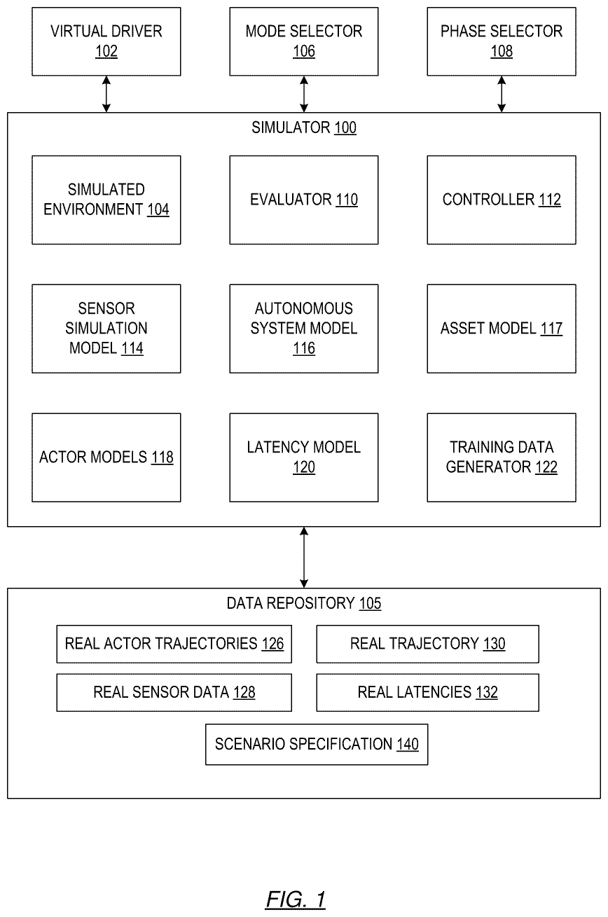

The testing and training of virtual driver of the autonomous systems in the real-world environment is unsafe because of the accidents that an untrained virtual driver can cause. Thus, as shown in FIG. 1, a simulator (100) is configured to train and test a virtual driver (102) of an autonomous system. For example, the simulator may be a unified, modular, mixed-reality, closed-loop simulator for autonomous systems. The simulator (100) is a configurable simulation framework that enables not only evaluation of different autonomy components in isolation, but also as a complete system in a closed-loop manner. The simulator reconstructs “digital twins” of real-world scenarios automatically, enabling accurate evaluation of the virtual driver at scale. The simulator (100) may also be configured to perform mixed-reality simulation that combines real world data and simulated data to create diverse and realistic evaluation variations to provide insight into the virtual driver's performance. The mixed reality closed-loop simulation allows the simulator (100) to analyze the virtual driver's action on counterfactual “what-if” scenarios that did not occur in the real-world. The simulator (100) further includes functionality to simulate and train on rare yet safety-critical scenarios with respect to the entire autonomous system and closed-loop training to enable automatic and scalable improvement of autonomy.

The simulator (100) creates the simulated environment (104) that is a virtual world in which the virtual driver (102) is the player in the virtual world. The simulated environment (104) is a simulation of a real-world environment, which may or may not be in actual existence, in which the autonomous system is designed to move. As such, the simulated environment (104) includes a simulation of the objects (i.e., simulated objects or assets) and background in the real world, including the natural objects, construction, buildings and roads, obstacles, as well as other autonomous and non-autonomous objects. The simulated environment simulates the environmental conditions within which the autonomous system may be deployed. Additionally, the simulated environment (104) may be configured to simulate various weather conditions that may affect the inputs to the autonomous systems. The simulated objects may include both stationary and non-stationary objects. Non-stationary objects are actors in the real-world environment.

The simulator (100) also includes an evaluator (110). The evaluator (110) is configured to train and test the virtual driver (102) by creating various scenarios the simulated environment. Each scenario is a configuration of the simulated environment including, but not limited to, static portions, movement of simulated objects, actions of the simulated objects with each other and reactions to actions taken by the autonomous system and simulated objects. The evaluator (110) is further configured to evaluate the performance of the virtual driver using a variety of metrics.

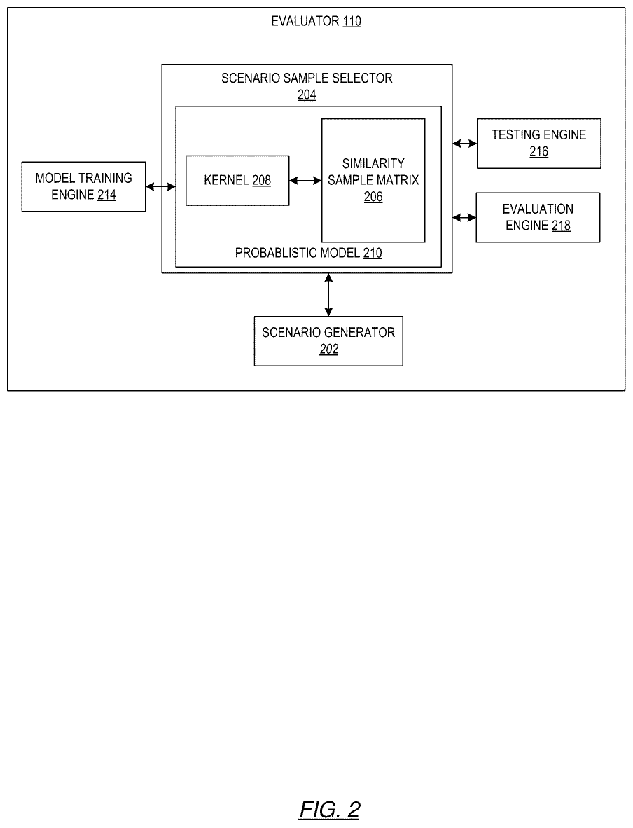

The evaluator (110) assesses the performance of the virtual driver throughout the performance of the scenario. Assessing the performance may include applying rules. For example, the rules may be that the automated system does not collide with any other actor, compliance with safety and comfort standards (e.g., passengers not experiencing more than a certain acceleration force within the vehicle), the automated system not deviating from executed trajectory), or other rule. Each rule may be associated with the metric information that relates a degree of breaking the rule with a corresponding score. The evaluator (110) may be implemented as a data-driven neural network that learns to distinguish between good and bad driving behavior. The various metrics of the evaluation system may be leveraged to determine whether the automated system satisfies the requirements of success criterion for a particular scenario. Further, in addition to system level performance, for modular based virtual drivers, the evaluator may also evaluate individual modules such as segmentation or prediction performance for actors in the scene with respect to the ground truth recorded in the simulator. The evaluator is further described in FIG. 2 below.

Continuing with FIG. 1, the simulator (100) is configured to operate in multiple phases as selected by the phase selector (108) and modes as selected by a mode selector (106). The phase selector (108) and mode selector (106) may be a graphical user interface or application programming interface component that is configured to receive a selection of phase and mode, respectively. The selected phase and mode define the configuration of the simulator (100). Namely, the selected phase and mode define which system components communicate and the operations of the system components.

The phase may be selected using a phase selector (108). The phase may be training phase or testing phase. In the training phase, the evaluator (110) provides metric information to the virtual driver (102), which uses the metric information to update the virtual driver (102). The evaluator (110) may further use the metric information to further train the virtual driver (102) by generating scenarios for the virtual driver. In the testing phase, the evaluator (110) does not provide the metric information to the virtual driver. In the testing phase, the evaluator (110) uses the metric information to assess the virtual driver and to develop scenarios for the virtual driver (102).

The mode may be selected by the mode selector (106). The mode defines the degree to which real-world data is used, whether noise is injected into simulated data, degree of perturbations of real-world data, and whether the scenarios are designed to be adversarial. Example modes include open loop simulation mode, closed loop simulation mode, single module closed loop simulation mode, fuzzy mode, and adversarial mode. In an open loop simulation mode, the virtual driver is evaluated with real world data. In a single module closed loop simulation mode, a single module of the virtual driver is tested. An example of a single module closed loop simulation mode is a localizer closed loop simulation mode in which the simulator evaluates how the localizer estimated pose drifts over time as the scenario progresses in simulation. In a training data simulation mode, simulator is used to generate training data. In a closed loop evaluation mode, the virtual driver and simulation system are executed together to evaluate system performance. In the adversarial mode, the actors are modified to perform adversarial. In the fuzzy mode, noise is injected into the scenario (e.g., to replicate signal processing noise and other types of noise). Other modes may exist without departing from the scope of the system.

The simulator (100) includes the controller (112) that includes functionality to configure the various components of the simulator (100) according to the selected mode and phase. Namely, the controller (112) may modify the configuration of the each of the components of the simulator based on configuration parameters of the simulator (100). Such components include the evaluator (110), the simulated environment (104), an autonomous system model (116), sensor simulation models (114), asset models (117), actor models (118), latency models (120), and a training data generator (122).

The autonomous system model (116) is a detailed model of the autonomous system in which the virtual driver will execute. The autonomous system model (116) includes model, geometry, physical parameters (e.g., mass distribution, points of significance), engine parameters, sensor locations and type, firing pattern of the sensors, information about the hardware on which the virtual driver executes (e.g., processor power, amount of memory, and other hardware information), and other information about the autonomous system. The various parameters of the autonomous system model may be configurable by the user or another system.

For example, if the autonomous system is a motor vehicle, the modeling and dynamics may include the type of vehicle (e.g., car, truck), make and model, geometry, physical parameters such as the mass distribution, axle positions, type and performance of engine, etc. The vehicle model may also include information about the sensors on the vehicle (e.g., camera, LiDAR, etc.), the sensors' relative firing synchronization pattern, and the sensors' calibrated extrinsics (e.g., position and orientation) and intrinsics (e.g., focal length). The vehicle model also defines the onboard computer hardware, sensor drivers, controllers, and the autonomy software release under test.

The autonomous system model includes an autonomous system dynamic model. The autonomous system dynamic model is used for dynamics simulation that takes the actuation actions of the virtual driver (e.g., steering angle, desired acceleration) and enacts the actuation actions on the autonomous system in the simulated environment to update the simulated environment and the state of the autonomous system. To update the state, a kinematic motion model may be used, or a dynamics motion model that accounts for the forces applied to the vehicle may be used to determine the state. Within the simulator, with access to real log scenarios with ground truth actuations and vehicle states at each time step, embodiments may also optimize analytical vehicle model parameters or learn parameters of a neural network that infers the new state of the autonomous system given the virtual driver outputs.

In one or more embodiments, the sensor simulation models (114) models, in the simulated environment, active and passive sensor inputs. Passive sensor inputs capture the visual appearance of the simulated environment including stationary and nonstationary simulated objects from the perspective of one or more cameras based on the simulated position of the camera(s) within the simulated environment. Example of passive sensor inputs include inertial measurement unit (IMU) and thermal. Active sensor inputs are inputs to the virtual driver of the autonomous system from the active sensors, such as LiDAR, RADAR, global positioning system (GPS), ultrasound, etc. Namely, the active sensor inputs include the measurements taken by the sensors, the measurements being simulated based on the simulated environment based on the simulated position of the sensor(s) within the simulated environment. By way of an example, the active sensor measurements may be measurements that a LiDAR sensor would make of the simulated environment over time and in relation to the movement of the autonomous system.

The sensor simulation models (114) are configured to simulates the sensor observations of the surrounding scene in the simulated environment (104) at each time step according to the sensor configuration on the vehicle platform. When the simulated environment directly represents the real-world environment, without modification, the sensor output may be directly fed into the virtual driver. For light-based sensors, the sensor model simulates light as rays that interact with objects in the scene to generate the sensor data. Depending on the asset representation (e.g., of stationary and nonstationary objects), embodiments may use graphics-based rendering for assets with textured meshes, neural rendering, or a combination of multiple rendering schemes. Leveraging multiple rendering schemes enables customizable world building with improved realism. Because assets are compositional in 3D and support a standard interface of render commands, different asset representations may be composed in a seamless manner to generate the final sensor data. Additionally, for scenarios that replay what happened in a real world and use the same autonomous system as in the real world, the original sensor observations may be replayed at each time step.

Asset models (117) includes multiple models, each model modeling a particular type of individual assets in the real world. The assets may include inanimate objects such as construction barriers or traffic signs, parked cars, and background (e.g., vegetation or sky). Each of the entities in a scenario may correspond to an individual asset. As such, an asset model, or instance of a type of asset model, may exist for each of the entities or assets in the scenario. The assets can be composed together to form the three-dimensional simulated environment. An asset model provides all the information needed by the simulator to simulate the asset. The asset model provides the information used by the simulator to represent and simulate the asset in the simulated environment. For example, an asset model may include geometry and bounding volume, the asset's interaction with light at various wavelengths of interest (e.g., visible for camera, infrared for LiDAR, microwave for RADAR), animation information describing deformation (e.g. rigging) or lighting changes (e.g., turn signals), material information such as friction for different surfaces, and metadata such as the asset's semantic class and key points of interest. Certain components of the asset may have different instantiations. For example, similar to rendering engines, an asset geometry may be defined in many ways, such as a mesh, voxels, point clouds, an analytical signed-distance function, or neural network. Asset models may be created either by artists, or reconstructed from real world sensor data, or optimized by an algorithm to be adversarial.

Closely related to, and possibly considered part of the set of asset models (117) are actor models (118). An actor model represents an actor in a scenario. An actor is a sentient being that has an independent decision-making process. Namely, in a real world, the actor may be animate being (e.g., person or animal) that makes a decision based on an environment. The actor makes active movement rather than or in addition to passive movement. An actor model, or an instance of an actor model may exist for each actor in a scenario. The actor model is a model of the actor. If the actor is in a mode of transportation, then the actor model includes the model of transportation in which the actor is located. For example, actor models may represent pedestrians, children, vehicles being driven by drivers, pets, bicycles, and other types of actors.

The actor model leverages the scenario specification and assets to control all actors in the scene and their actions at each time step. The actor's behavior is modeled in a region of interest centered around the autonomous system. Depending on the scenario specification, the actor simulation will control the actors in the simulation to achieve the desired behavior. Actors can be controlled in various ways. One option is to leverage heuristic actor models, such as intelligent-driver model (IDM) that try to maintain a certain relative distance or time-to-collision (TTC) from a lead actor or heuristic-derived lane-change actor models. Another is to directly replay actor trajectories from a real log, or to control the actor(s) with a data-driven traffic model. Through the configurable design, embodiments may can mix and match different subsets of actors to be controlled by different behavior models. For example, far-away actors that initially may not interact with the autonomous system and can follow a real log trajectory, but when near the vicinity of the autonomous system may switch to a data-driven actor model. In another example, actors may be controlled by a heuristic or data-driven actor model that still conforms to the high-level route in a real-log. This mixed-reality simulation provides control and realism.

Further, actor models may be configured to be in cooperative or adversarial mode. In cooperative mode, the actor model models actors to act rationally in response to the state of the simulated environment. In adversarial mode, the actor model may model actors acting irrationally, such as exhibiting road rage and bad driving.

The latency model (120) represents timing latency that occurs when the autonomous system is in the real-world environment. Several sources of timing latency may exist. For example, a latency may exist from the time that an event occurs to the sensors detecting the sensor information from the event and sending the sensor information to the virtual driver. Another latency may exist based on the difference between the computing hardware executing the virtual driver in the simulated environment as compared to the computing hardware of the virtual driver. Further, another timing latency may exist between the time that the virtual driver transmits an actuation signal to the autonomous system changing (e.g., direction or speed) based on the actuation signal. The latency model (120) models the various sources of timing latency.

Stated another way, in the real world, safety-critical decisions in the real world may involve fractions of a second affecting response time. The latency model simulates the exact timings and latency of different components of the onboard system. To enable scalable evaluation without strict requirement on exact hardware, the latencies and timings of the different components of autonomous system and sensor modules are modeled while running on different computer hardware. The latency model may replay latencies recorded from previously collected real world data or have a data-driven neural network that infers latencies at each time step to match the hardware in loop simulation setup.

The training data generator (122) is configured to generate training data. For example, the training data generator (122) may modify real-world scenarios to create new scenarios. The modification of real-world scenarios is referred to as mixed reality. For example, mixed-reality simulation may involve adding in new actors with novel behaviors, changing the behavior of one or more of the actors from the real-world, and modifying the sensor data in that region while keeping the remainder of the sensor data the same as the original log. In some cases, the training data generator (122) converts a benign scenario into a safety-critical scenario.

The simulator (100) is connected to a data repository (105). The data repository (105) is any type of storage unit or device that is configured to store data. The data repository (105) includes data gathered from the real world. For example, the data gathered from the real world include real actor trajectories (126), real sensor data (128), real trajectory of the system capturing the real world (130), and real latencies (132). Each of the real actor trajectories (126), real sensor data (128), real trajectory of the system capturing the real world (130), and real latencies (132) is data captured by or calculated directly from one or more sensors from the real world (e.g., in a real-world log). In other words, the data gathered from the real-world are actual events that happened in real life. For example, in the case that the autonomous system is a vehicle, the real-world data may be captured by a vehicle driving in the real world with sensor equipment.

Further, the data repository (105) includes functionality to store one or more scenario specifications (140). A scenario specification (140) specifies a scenario and evaluation setting for testing or training the autonomous system. For example, the scenario specification (140) may describe the initial state of the scene, such as the current state of autonomous system (e.g., the full 6D pose, velocity and acceleration), the map information specifying the road layout, and the scene layout specifying the initial state of all the dynamic actors and objects in the scenario. The scenario specification may also include dynamic actor information describing how the dynamic actors in the scenario should evolve over time which are inputs to the actor models. The dynamic actor information may include route information for the actors, desired behaviors or aggressiveness. The scenario specification (140) may be specified by a user, programmatically generated using a domain-specification-language (DSL), procedurally generated with heuristics from a data-driven algorithm, or adversarial. The scenario specification (140) can also be conditioned on data collected from a real-world log, such as taking place on a specific real-world map or having a subset of actors defined by their original locations and trajectories.

The interfaces between virtual driver and the simulator match the interfaces between the virtual driver and the autonomous system in the real world. For example, the sensor simulation model (114) and the virtual driver matches the virtual driver interacting with the sensors in the real world. The virtual driver is the actual autonomy software that executes on the autonomous system. The simulated sensor data that is output by the sensor simulation model (114) may be in or converted to the exact message format that the virtual driver takes as input as if the virtual driver were in the real world, and the virtual driver can then run as a black box virtual driver with the simulated latencies incorporated for components that run sequentially. The virtual driver then outputs the exact same control representation that it uses to interface with the low-level controller on the real autonomous system. The autonomous system model (116) will then update the state of the autonomous system in the simulated environment. Thus, the various simulation models of the simulator (100) run in parallel asynchronously at their own frequencies to match the real-world setting.

FIG. 2 shows an expanded diagram of the evaluator (110). As discussed above, the evaluator controls the training or testing of the autonomous system. The evaluator includes a scenario generator (202) connected to a scenario sample selector (204). The components of the scenario sample selector (204) are trained by a model training engine (214). The scenario sample selector (204) is also communicatively connected to a testing engine (216) and an evaluation engine (218). Each of the components of the evaluator (110) are described below.

In one or more embodiments, the scenario generator (202) is software configured to obtain a specification of a scenario and instantiate an instance of the scenario sample selector (204) for the scenario. A scenario is a description of the semantics of a virtual environment through which the autonomous system is designed to move. Namely, a scenario describes a general event or sequence of events in the virtual environment to test or train the autonomous system.

The specification of the scenario describes the scenario and defines the parameters of the scenario. The parameters of the scenario specify low-level characteristics of the scenario. In particular, the parameters are the more specific set of attributes of the general situation. By way of an example, the scenario may be a non-stationary object moving in front of the autonomous system and the parameters may be the type of object, size of object, velocity, and information about other objects around the autonomous system or in the environment. Some of the parameters may be static parameters. Static parameters are parameters whose values do not change between samples. For example, static parameters have a value defined in the Specification. At least some of the parameters are modifiable parameters. Modifiable parameters are parameters whose values may be modified to perform different tests for the scenario. Specifically, the modifiable parameters are sampled to generate a sample for testing.

Modifiable parameters may be continuous parameters, discrete parameters, or categorical parameters. Continuous parameters are parameters whose values may be any value defined in continuous space. Continuous parameters may be within a defined range of values. For example, the continuous parameters may be velocity, acceleration, color, etc. Discrete parameters are sampled from a discrete set of values. For example, the discrete parameters may include a level of aggressiveness of other actors, a number of other actors, and other values. Categorical parameters may include the type of objects in the environment. For example, the categorical parameters may be the type of other objects in the environment. Different actors and other objects in the environment may have different sets of static or modifiable parameters. For example, some of the actors may have modifiable parameters of velocity, type of actor, starting position, and goal location, while other actors have the same parameters as static.

The specification of the scenario includes definitions of the virtual environment in which the autonomous as well as static and modifiable parameters. For example, the definitions of the environment may include map data, types of sensors on the autonomous system, and other aspects. The specification also defines which parameters are static and which parameters are modifiable is defined in the specification. For modifiable parameters, the specification defines the set of values of the parameters or the range of values of the modifiable parameter.

Continuing with FIG. 2, a scenario sample selector (204) is configured to select a sample for a scenario using the specification based on outcomes of past tests. Generally, the scenario sample selector (204) is configured to sample tests to cover the parameter space; and estimate pass and fail of the system across the parameter space. A sample is a set of parameter values that is designed for a test. The scenario sample selector (204) includes a probabilistic model (210) having a similarity sample matrix (206) connected to a kernel (208).

The probabilistic model (210) is a model that generates probabilities. The probabilistic model (210) is configured to determine a probability of pass, fail, or unknown for a sample. For example, the probabilistic model may separate the sample space into one or more pass regions, one or more fail regions, and one or more unknown regions. The sample space are the possible values of the modifiable parameters. In one or more embodiments, the probabilistic model is a multivariate Gaussian model, whereby the variables are the parameters.

The similarity sample matrix (206) includes a measure of similarity between pairs of samples. For example, the similarity sample matrix (206) may be a covariance matrix that has the covariance between samples. The similarity measure is based, in part, on the performance of the virtual driver in the samples in one or more embodiments. Thus, when tests of two samples have the same outcome by the virtual driver, the similarity measure between the two tests is greater. Conversely, when tests of two samples have the different outcome by the virtual driver, the similarity measure between the two tests is lower.

The kernel (208) is a model that is configured to calculate the similarities in the similarity sample matrix. The kernel (208) is a model that is trained to learn how to measure the similarity based on the performance of the virtual driver. In some embodiments, the kernel treats the modifiable parameters as independent variables. The kernel generates an intermediate similarity value independently for each parameter. The kernel then trained to combine the intermediate independently generated similarity value into a combined similarity value for two samples. The training of the kernel accounts for the performance of the virtual driver.

The probabilistic model (210) is connected to a model training engine (214). The model training engine (214) is configured to train the probabilistic model (210). Specifically, the model training engine (214) is configured to train the kernel to calculate similarity between samples and to train the probabilistic model to accurately determine the pass, fail, and unknown regions.

The scenario sample selector (204) is connected to a testing engine (216). The testing engine (216) is configured to test the virtual driver. Specifically, the testing engine (216) is configured to formulate a test from a sample. The testing engine may be configured to trigger a test using the simulator.

The evaluation engine (218) is configured to evaluate the virtual driver based on the execution by the virtual driver in the simulation. For example, the evaluation may be based on one or more criteria. For example, the criteria may be the estimated distance between the virtual driver and other actors and objects, the smoothness of the simulated autonomous system, and other criteria.

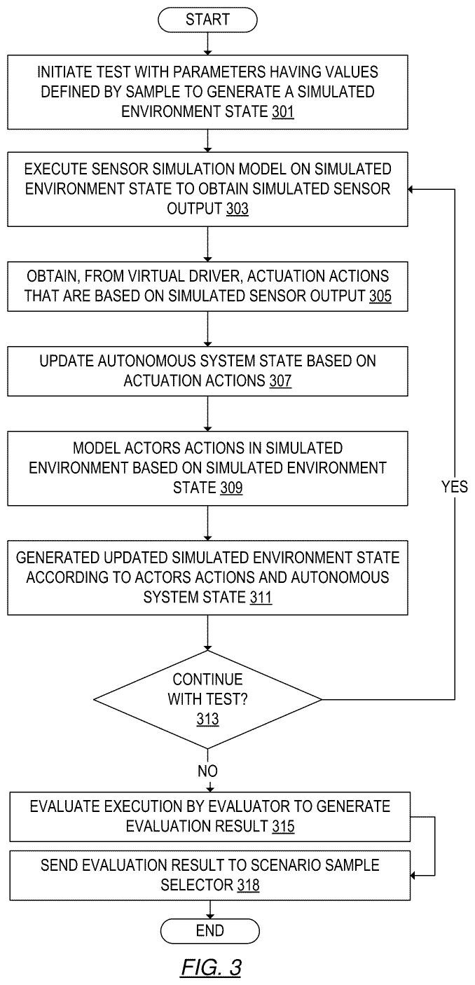

The testing and evaluation of the virtual driver is described in FIG. 3. FIG. 3 shows a flow diagram for executing the simulator in a closed loop mode.

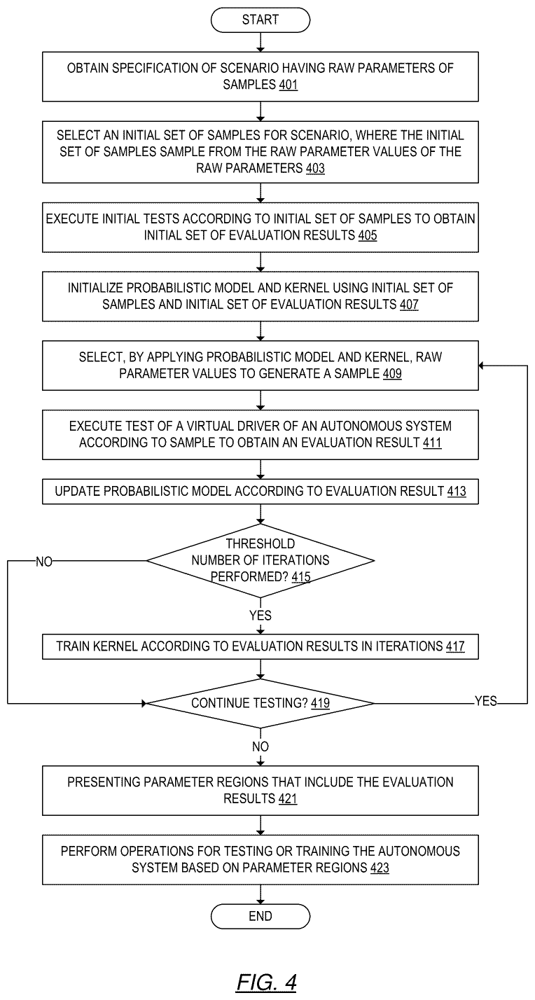

In Block 301, a test is initiated with parameters having values defined by a sample to generate a simulated environment state. The specification is used as input of the first portion of the test. Modifiable parameters are sampled by the scenario sample selector to generate a sample for the remaining portion of the test. The generating the sample of modifiable parameters is described in FIG. 4. The complete set of parameters (i.e., the values of the static parameter in the specification and the values of the modifiable parameters defined by the sample) are used by the simulator to initialize a test.

Map data and background data is used to generate a virtual world as defined by the specification. To initialize the test, the simulator creates a background of the virtual world as defined by the specification. For example, the background may be a model of the real world, for objects that are more than a predefined distance from the autonomous system.

In some embodiments, the simulator generates a digital twin of a real-world scenario as an initial simulated environment state. Log data from the real world is used to generate an initial virtual world. The log data defines which asset and actor models are used in an initial positioning of assets. For example, using convolutional neural networks on the log data, the various asset types within the real world may be identified. As other examples, offline perception systems and human annotations of log data may be used to identify asset types. In such a scenario, corresponding asset and actor models may be identified based on the asset types and add to the positions of the real actors and assets in the real world.

The parameters of the specification and sample may define modifications to the real-world to create the virtual world. For example, the parameters may define the type and initial placement of assets and actors in the virtual world. Corresponding asset and actor models are obtained as identified in the specification and sample. The corresponding asset and actor models are rendered in the virtual world using the values of various parameters.

Further, the parameters, static or modifiable, may specify the current conditions of the virtual world. For example, the parameters may specify weather, visibility, lighting, time of day, and other aspects.

Accordingly, the parameters combined with the asset and actor models with the background as defined by the specification and sample create an initial three-dimensional virtual world. The initial three-dimensional virtual world forms a simulated environment state.

In Block 303, the sensor simulation model is executed on the simulated environment state to obtain simulated sensor output. The sensor simulation model may use beamforming and other techniques to replicate the view to the sensors of the autonomous system. Each sensor of the autonomous system has a corresponding sensor simulation model and a corresponding system. The sensor simulation model executes based on the position of the sensor within the virtual environment and generates simulated sensor output. The simulated sensor output is in the same form as would be received from a real sensor by the virtual driver.

The simulated sensor output is passed to the virtual driver. In Block 305, the virtual drive executes based on the simulated sensor output to generate actuation actions. The actuation actions define how the virtual driver controls the autonomous system. For example, for a self-driving vehicle, the actuation actions may be amount of acceleration, movement of the steering, triggering of a turn signal, etc. From the actuation actions, the autonomous system state in the simulated environment is updated in Block 307. The actuation actions are used as input to the autonomous system model to determine the actual actions of the autonomous system. For example, the autonomous system dynamic model may use the actuation actions in addition to road and weather conditions to represent the resulting movement of the autonomous system. For example, in a wet or snow environment, the same amount of acceleration action as in a dry environment may cause less acceleration than in the dry environment. As another example, the autonomous system model may account for possibly faulty tires (e.g., tire slippage), mechanical based latency, or other possible imperfections in the autonomous system.

In Block 309, actors' actions in the simulated environment are modeled based on the simulated environment state. Concurrently with the virtual driver model, the actor models and asset models are executed on the simulated environment state to determine an update for each of the assets and actors in the simulated environment. Here, the actors' actions may use the previous output of the evaluator to test the virtual driver. For example, if the actor is adversarial, the evaluator may indicate based on the previous action of the virtual driver, the lowest scoring metric of the virtual driver. Using a mapping of metrics to actions of the actor model, the actor model executes to exploit or test that particular metric.

The actor actions may also be defined by the static and/or modifiable parameters. For example, the actor actions may include the goal locations of actors, the degree of aggressiveness (e.g., the amount of space that the actor requires to switch lanes), acceleration and velocity, and other attributes of the actor. The goal location of the actor is the target position of the particular actor within a certain number of timesteps. For example, similar to the way in which each person driving a vehicle has a destination location that affects the path that the person takes driving the vehicle, in the virtual world, each actor has a goal location. The goal location is a destination location that defines the path of the actor in the virtual world.

Thus, in Block 311, the updated simulated environment state is updated according to the actors' actions and the autonomous system state. The updated simulated environment includes the change in positions of the actors and the autonomous system. Because the models execute independently of the real world, the update may reflect a deviation from the real world.

In Block 313, a determination is made whether to continue with the test. If the determination is made to continue, testing of the autonomous system continues using the updated simulated environment state in Block 303. Thus, the virtual driver continues to cause the autonomous system to move to the virtual driver's predefined goal location while reacting to the current simulated environment state.

In Block 315, at any time or at the end of training, the evaluator evaluates the execution by the virtual driver to obtain an evaluation result. Evaluation is performed along a set of one or more criteria. The set of one or more criteria may include, for example, whether the autonomous system collided with another object in the simulation, smoothness of the virtual driver, speed, distance between the autonomous system and other drivers or objects, degree to which the autonomous system keep with a direct path to the goal location, etc. Some of the criteria has a binary question while other criteria may involve comparing the actions of the autonomous systems to one or more thresholds. The evaluator may aggregate the results across the set of criteria to obtain an evaluation result. The evaluation result may include pass or fail. Pass indicates that the virtual driver passed the test whereas fail indicates that the virtual driver did not pass the test.

In Block 318, the evaluation result is transmitted to the scenario sample detector. Sending the evaluation result may be to respond to the scenario sample selector with the evaluation result or storing the evaluation result in a storage location associated with the sample. Thus, the scenario sample detector has the sample related to the evaluation result as a ground truth value for additional sampling in accordance with one or more embodiments. The scenario sample detector uses the evaluation result to select additional samples as described in FIG. 4.

In one or more embodiments, the evaluator may provide feedback to the virtual driver. In such embodiments, the parameters of the virtual driver may be updated to improve performance of the virtual driver in a variety of scenarios.

Although FIG. 3 shows performance of a single test, during testing, the evaluator is able to test from samples generated for a variety of scenarios including edge cases that may be safety critical. The performance across of the virtual driver across hundreds of thousands of tests in thousands of scenarios improves the performance of the virtual driver. Thus, one or more embodiments improve the virtual driver and increase safety of the virtual driver in the real world.

As shown, the virtual driver of the autonomous system acts based on the test and the current learned parameters of the virtual driver. The simulator obtains the actions of the autonomous system and provides a reaction in the simulated environment to the virtual driver of the autonomous system. The evaluator evaluates the performance of the virtual driver and creates scenarios based on the performance. The process may continue as the autonomous system operates in the simulated environment.

FIG. 4 shows a flowchart for generating samples for a virtual driver in accordance with one or more embodiments. The process of FIG. 4 is performed for each specification of a scenario that is received. Thus, multiple independent instances of the scenario sample selectors may exist. In Block 401, a definition of a scenario having raw parameters to samples is obtained. The raw parameters are the continuous or discrete set of values that the parameters may be. In one or more embodiments, raw parameters are not discretized to perform the sampling. Namely, raw parameters are kept in the continuous space. A user or other entity may generate a specification of a scenario, such as by using an interactive graphical user interface.

When a specification is received, the scenario generator may initialize a scenario sample selector for the new scenario. Thus, in one or more embodiments, a new probability model and a new kernel is generated specifically for the scenario. In one or more embodiments, the probability model and the kernel may be pretrained models that is further trained for the particular scenario.

In Block 403, an initial set of samples for the scenario is selected, where the initial set of samples are sampled from the raw parameter values. To generate a sample, for each raw modifiable parameter, the scenario sample selector randomly selects or otherwise randomly generates values of the parameters based on the range of the parameter as defined by the specification. The group of values of the modifiable parameters are combined into a sample. Multiple samples may be generated.

In Block 405, initial tests are executed according to the initial set of samples to obtain an initial set of evaluation results. Each sample is used to initialize a corresponding test. The test is executed as described above with reference to FIG. 3. The simulator evaluates the virtual driver and outputs an evaluation result. Thus, each sample may be related to a corresponding particular evaluation result. The set of samples and corresponding evaluation results form a ground truth for training.

In Block 407, the probabilistic model and the kernel are initialized using the initial set of samples and the initial set of evaluation results.

The initialization of the probabilistic model may be performed while the initial set of samples are generated and tested. For example, at each iteration of generating a sample in the initial set of samples and generating a test in Blocks 403 and 405, the probabilistic model may be executed. The probabilistic model partitions the sample space into a pass region, a fail region, and an unknown region. The pass region is the contiguous or non-contiguous region of the sample space in which the confidence level of the predicted evaluation result being a pass is greater than a first threshold. The fail region is the contiguous or non-contiguous region of the sample space in which the confidence level of the predicted evaluation result being a fail is greater than a second threshold. The first threshold and the second threshold may be different or the same. The unknown region is the region in which the confidence level does not satisfy the first or second threshold.

A Gaussian process may be used as the probabilistic model that uses the similarity measure between the samples to perform the prediction. Prior to the initialization of the kernel in Block 407, the similarity measure between two samples may be based on the distance between the two samples in the sample space. For example, when the kernel is not initialized, the similarity measure between samples may be calculated as a combination a normalized distances between the respective sample values of the parameters. Samples that are neighbors in the sample space are assumed to be a higher similarity measure than samples that are farther apart and, therefore, more likely to have the same predicted evaluation result.

In the probabilistic model, prior to any tests being performed, the entire sample space is an unknown region. However, as more samples are generated and tests are performed, the probabilistic model calculates the probabilities of pass and fail in the different regions based on the similarity measure between samples. Thus, more and more regions become predicted as either pass or fail regions.

Sample selection may be performed using the pass region, the fail region, and the unknown region from the probabilistic model. Specifically, the samples are selected that are in the unknown region or the boundary between pass region and fail region.

After testing of an initial set of samples, the kernel may be trained on the initial batch of evaluation results. Specifically, the kernel is trained to compute the similarity between samples such that the probabilistic model accurately predicts the evaluation result. Namely, the prediction for an initial sample is compared to the outcome of the initial sample in the ground truth. The result is used to update the similarity measure.

After the updating of the kernel, the probabilistic model is updated to generate a new prediction of the sample space. Namely, the updating of the kernel may cause a shift in the similarity measure between samples. Thus, the probabilistic model is executed using the new kernel to generate an updated sample space.

Continuing with FIG. 4, Blocks 409-419 is directed to an iterative process to continually update the sample space. In Block 409, by applying the probabilistic model and the kernel, raw parameter values are selected to generate a sample. As described above, the kernel calculates the similarity measure between the samples. The kernel may calculate the similarity sample matrix. The probability model uses the similarity measure between the samples to partition the sample space into a pass region, fail region, and unknown region. Selecting the set of raw parameter values may be performed by determining, in the sample space, a sample that has an unknown predicted evaluation result or which has an evaluation result within a threshold of a border between a pass region and a fail region. The set of parameter values are combined into a sample.

In Block 411, a test is executed on the sample to generate an evaluation result. Executing the test is described in reference to FIG. 3.

In Block 413, the probabilistic model is update according to the evaluation result. Specifically, as new ground truth data is obtained, the predicted evaluation results and corresponding confidence levels may be recomputed based on the similarity measure between the sample for which the test is executed and other samples. Thus, the pass region, fail region, and unknown region may be updated with each test.

In Block 415, a determination is made whether a threshold number of iterations are performed. If a threshold number of iterations are performed, then the kernel is retrained in Block 417. The retraining of the kernel is performed to generate a more accurate similarity measure between samples. Training the kernel is performed as described in reference to Block 407. In one or more embodiments, after retraining the kernel, the probabilistic model may be updated with the new similarity measures generated by the kernel.

In Block 419, if a threshold number of iterations are not performed or after updating the probabilistic model, a determination is made whether to continue testing. If unknown regions exist, testing may continue for the unknown regions. When testing complete, the process flows to Block 421.

In Block 421, parameter regions that includes the evaluation results is presented. In particular, the parameter regions are the sample regions as related to the pass region, the fail region and the unknown region. Presenting the parameter regions may be to display the parameter regions in a graphical user interface or transmit the parameter regions to a different component of the autonomous testing and training system.

In Block 423, operations for testing or training the autonomous system is performed based on the parameter regions. The code of the virtual driver may be updated based on the fail region. As another example, the autonomous system may be updated with more sensors or different sensor placement based on the fail regions. As another example, the virtual driver and the autonomous system may be determined to pass testing based on the parameter regions and deployed to the real world.

Because the raw parameter values are used to perform the sampling, a more precise set of parameter regions of the pass, fail, and unknown regions is generated. Thus, the operations on the autonomous system may be more precise.

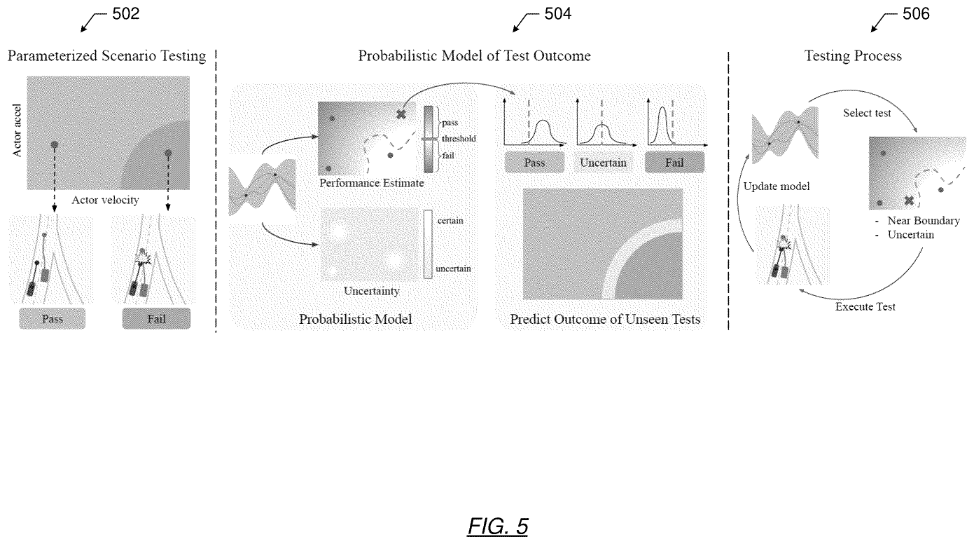

FIG. 5 shows an example of validation of an autonomous system in accordance with one or more embodiments. The example of FIG. 5 is shown for explanatory purposes only and not intended to limit the scope of the claims.

In the example of FIG. 5, the autonomous system is a self-driving vehicle (SDV). The scenario has two modifiable parameters of another actor in the scenario. The left side (502) of the FIG. 5 shows the parameterized scenario testing. As shown, the modifiable parameters are actor acceleration (on the vertical axis of the graph) and actor velocity (on the right side of the graph). The pass region is the region in which the SDV and the actor did not collide, while the fail region is the region in which the actor collided.

To determine the pass and fail region, samples are selected using a probabilistic model (as shown in center pane (504)). The probabilistic model generates a performance estimate and corresponding uncertainties for each location in the sample region. In the example, the first and second thresholds are the same for whether the virtual driver is determined to pass or fail.

The testing process (as shown in the right pane (506)) shows the iterative process for performing tests. In the iterative process, a sample for the test is selected based on the boundary and uncertainty. A test is executed according to the sample to generate an evaluation result. The evaluation result is used to update the model. The process repeats until a stop condition is reached.

The following is an example description of how the validation of the autonomous system may be performed using a Gaussian model. The following example is for illustrative purposes and provides on implementation. Other techniques may be used without departing from the scope of the claims.

Each scenario has a set of d configurable parameters θ∈R^{d}, where each specific configuration of the parameters results in a concrete test. The scenario parameters are bounded (i.e., θᵢ∈[aᵢ, bᵢ] making the entire parameter search space a closed set Θ in R^{d}. One or more embodiments assume that a simulation test outputs a scalar measure of safety (e.g., a minimum distance to another agent). Mathematically, let ƒ*: θ×A→R be the test function which takes as input test parameters θ, autonomy system A and outputs a real-valued scalar ƒ*(θ;A). A is omitting in the following to use ƒ*(θ) for simplicity of explanation. Namely, ƒ*(θ) is the raw evaluation result of the virtual driver on a test generated with sample set of parameters θ. A binary pass or fail (i.e., y=1[ƒ*(θ)≥γ]) is computed using a threshold γ. Thus, pass region and the fail region in the parameter space Θ where the system passes and fails may be denoted as:

$${P}^{*} = \{ θ ∈ Θ , {f}^{*} ( θ ) \geq γ \} . \qquad ( 1 )$$

$${F}^{*} = \{ θ ∈ Θ , {f}^{*} ( θ ) < γ \} . \qquad ( 2 )$$

The testing process is a sequence a finite set of tests {θ₁, . . . , θ_{N}}, observing the evaluation results {ƒ*(θ₁), . . . ƒ*(θ_{N})} and estimating the probabilities of the pass region P≈P* and the fail region F≈F*. Estimating pass/fail across a continuous parameter domain using a finite set of test points generally leads to estimation errors, especially if the number of concrete tests is limited (e.g., due to testing resource constraints). At the same time, estimation errors and false positive passes in particular can be detrimental to safety.

Because of the problems of estimation errors, one or more embodiments design an uncertainty-aware formulation where the system quantifies the confidence of the system's estimation. Using the quantified confidence level, an uncertain region is added instead of predicting a pass/fail outcome with insufficient information. Specifically, one or more embodiments compute the probability that the system will pass or fail at any point in the parameter space. To compute the probability, ƒ*(θ) is modeled with a random variable ƒ(θ). Under the random variable ƒ(θ), the estimated pass and fail regions is be defined as

$$\begin{matrix}P = \{ θ ∈ Θ , P ( f ( θ ) \geq γ ) \geq α \} . \\ F = \{ θ ∈ Θ , P ( f ( θ ) < γ ) \geq α \} .\end{matrix} \qquad ( 3 )$$

In equation (3), the confidence threshold is α. Thus, for the example, the unknown region is U=Θ−P−F. In the unknown region, more information is required to make a prediction for a particular confidence threshold. The size of P and F increase monotonically as a decreases. The configurable confidence threshold α allows the testing framework to control the tradeoff between the quality and quantity of predictions.

A probabilistic estimate ƒ(θ) is used for the ground truth test function ƒ*(θ). In the example, a Gaussian Process (GP) is used because GP may perform well in low-data regimes in which tests are limited. Because the GP is non-parametric and make less assumptions about the function being modeled, the GP may scale to a wide variety of logical scenarios.

A GP is a collection of random variables in which every subset is assumed to distributed from a multivariate Gaussian. Let X=[θ₁ . . . . θ_{N}]∈R^{n×d}˜N(μ, Σ) be random variables from N test samples and Y=[ƒ*(θ₁) . . . ƒ*(θ_{N})] be the corresponding scalar outputs of ƒ*. To estimate test outcomes, one or more embodiments model the distribution over the real-valued output of the metric P(ƒ(θ)). Specifically, the value of an unseen datapoint is estimated by the conditional posterior distribution:

$$P ( f ( θ ) \vert θ , X , Y ) \sim N ( μ ( θ ) , {σ}^{2} ( θ ) ) \qquad ( 4 )$$

$$μ ( θ ) = {k ( θ , X )}^{T} {( K + {ϵ}^{2} I )}^{- 1} Y \qquad ( 5 )$$

$${σ}^{2} ( θ ) = k ( θ , θ ) - {k ( θ , X )}^{T} {( K + {ϵ}^{2} I )}^{- 1} k ( θ , X ) \qquad ( 6 )$$

In the above equations, k(⋅,⋅) is the kernel function which provides a similarity measure between two GP variables, k(θ,X)=[k(θ,θᵢ), . . . , k(θ,θ_{N})], Kᵢⱼ=k(θᵢ,θⱼ), and models noise in the observed values Y. Under the posterior distribution of ƒ(θ), the probability of observing a value above or below the pass/fail threshold γ can be computed. Specifically, the probability of observing a value greater than the pass-fail threshold γ is:

$$P ( f ( θ ) \geq γ ) = Φ ( \frac{μ ( θ ) - γ}{σ ( θ )} ) \qquad ( 7 )$$

In equation (7), Φ is the cumulative distribution function (CDF) of the normal distribution. The probability of observing a value under the pass/fail threshold γ (i.e., the probability of a failing test) may be computed in a similar fashion.

Precisely modelling ƒ*(θ) when the raw evaluation result far from pass/fail threshold γ adds little value since the precise modeling does not affect the pass or fail outcome. In contrast, accurately modeling regions near the γ-levelset is more important. Hence, one or more embodiments may leverage levelset algorithms to efficiently upsample points near the boundary of between the pass and fail regions. For example, the algorithm Straddle may be used because Straddle directly integrates GPs. Straddle iteratively queries test points based on an exploration incentive promoting points with high variance and an exploitation incentive promoting points close to the γ-levelset. Specifically, the two exploration and exploitation incentives may be captured by the acquisition function:

$${h}_{t} ( θ ) = B {σ}_{t} ( θ ) - \vert {μ}_{t} ( θ ) - γ \vert \qquad ( 8 )$$

In equation (8), β is a weighting coefficient balancing the first exploration term and the second exploitation term. At each iteration, one or more embodiments solve a lightweight maximization problem to find the next query point θₜ=argmaxθ hₜ(θ). One or more embodiments may start by sampling P initial random points from Θ. Since hₜ(θ) is differentiable with respect to θ, the top Q candidates may be improved via gradient-based optimization. The gradient-based optimization is inexpensive since the cost of running the GP model and performing backpropagation to evaluate μ(θ), σ(θ) is negligible compared to running simulation to evaluate ƒ*(θ). Finally, the concrete test corresponding to θₜ is executed in simulation to obtain ƒ*(θₜ). The observation (θₜ, ƒ*(θₜ)) is then added to the GP model to update the GP posterior.

In addition to observed test points, the posterior distribution outlined in Equation (5) and (6) depend on the kernel function k(⋅,⋅). Thus, the estimates P and F are sensitive to the kernel function parameters which is denoted as κ. Further, in one or more embodiments, each individual scenario has different parameters with varying scales and effects on the final output, requiring different kernels to accurately model different scenarios.

To circumvent this issue, one or more embodiments may first normalize the scenario parameter space Θ to the unit hypercube [0,1]^{d} to address parameters with different scales. Furthermore, instead of manually tuned and fixed kernel parameters, one or more embodiments may optimize the kernel parameters to maximize the marginal likelihood of the observations. In particular, at iteration t, one or more embodiments update the kernel parameters κ towards

$${κ}_{t} = arg {max}_{κ} P ( f ( {θ}_{1} ) … f ( {θ}_{t} ) \vert {θ}_{1} … {θ}_{t} ; κ ) \qquad ( 9 )$$

The marginal likelihood is differentiable with respect to the kernel parameters κₜ. Gradient-based optimization may be performed every K iterations. The kernel learning process can be prone to overfitting to a small initial batch of observations. Therefore, one or more embodiments perform an initial sampling step where M tests are queried using only the variance term σₜ(θ) of the acquisition function outlined in Equation 8.

Embodiments may be implemented on a computing system specifically designed to achieve an improved technological result. When implemented in a computing system, the features and elements of the disclosure provide a significant technological advancement over computing systems that do not implement the features and elements of the disclosure. Any combination of mobile, desktop, server, router, switch, embedded device, or other types of hardware may be improved by including the features and elements described in the disclosure. For example, as shown in FIG. 3A, the computing system (300) may include one or more computer processors (302), non-persistent storage (304), persistent storage (306), a communication interface (312) (e.g., Bluetooth interface, infrared interface, network interface, optical interface, etc.), and numerous other elements and functionalities that implement the features and elements of the disclosure. The computer processor(s) (302) may be an integrated circuit for processing instructions. The computer processor(s) may be one or more cores or micro-cores of a processor. The computer processor(s) (302) includes one or more processors. The one or more processors may include a central processing unit (CPU), a graphics processing unit (GPU), a tensor processing unit (TPU), combinations thereof, etc.

The input devices (310) may include a touchscreen, keyboard, mouse, microphone, touchpad, electronic pen, or any other type of input device. The input devices (310) may receive inputs from a user that are responsive to data and messages presented by the output devices (308). The inputs may include text input, audio input, video input, etc., which may be processed and transmitted by the computing system (300) in accordance with the disclosure. The communication interface (312) may include an integrated circuit for connecting the computing system (300) to a network (not shown) (e.g., a local area network (LAN), a wide area network (WAN) such as the Internet, mobile network, or any other type of network) and/or to another device, such as another computing device.

Further, the output devices (308) may include a display device, a printer, external storage, or any other output device. One or more of the output devices may be the same or different from the input device(s). The input and output device(s) may be locally or remotely connected to the computer processor(s) (302). Many different types of computing systems exist, and the aforementioned input and output device(s) may take other forms. The output devices (308) may display data and messages that are transmitted and received by the computing system (300). The data and messages may include text, audio, video, etc., and include the data and messages described above in the other figures of the disclosure.

Software instructions in the form of computer readable program code to perform embodiments may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments, which may include transmitting, receiving, presenting, and displaying data and messages described in the other figures of the disclosure.

The computing system (300) in FIG. 3A may be connected to or be a part of a network. For example, as shown in FIG. 3B, the network (320) may include multiple nodes (e.g., node X (322), node Y (324)). Each node may correspond to a computing system, such as the computing system shown in FIG. 3A, or a group of nodes combined may correspond to the computing system shown in FIG. 3A. By way of an example, embodiments may be implemented on a node of a distributed system that is connected to other nodes. By way of another example, embodiments may be implemented on a distributed computing system having multiple nodes, where each portion may be located on a different node within the distributed computing system. Further, one or more elements of the aforementioned computing system (300) may be located at a remote location and connected to the other elements over a network.

The nodes (e.g., node X (322), node Y (324)) in the network (320) may be configured to provide services for a client device (326), including receiving requests and transmitting responses to the client device (326). For example, the nodes may be part of a cloud computing system. The client device (326) may be a computing system, such as the computing system shown in FIG. 3A. Further, the client device (326) may include and/or perform all or a portion of one or more embodiments.

The computing system of FIG. 3A may include functionality to present raw and/or processed data, such as results of comparisons and other processing. For example, presenting data may be accomplished through various presenting systems. Specifically, data may be presented by being displayed in a user interface, transmitted to a different computing system, and stored. The user interface may include a GUI that displays information on a display device. The GUI may include various GUI widgets that organize what data is shown as well as how data is presented to a user. Furthermore, the GUI may present data directly to the user, e.g., data presented as actual data values through text, or rendered by the computing device into a visual representation of the data, such as through visualizing a data model.

As used herein, the term “connected to” contemplates multiple meanings. A connection may be direct or indirect (e.g., through another component or network). A connection may be wired or wireless. A connection may be temporary, permanent, or semi-permanent communication channel between two entities.

The various descriptions of the figures may be combined and may include or be included within the features described in the other figures of the application. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, or is an “inclusive or” and, as such includes “and.” Further, items joined by an or may include any combination of the items with any number of each item unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. A method comprising:
generating a first sample comprising a first plurality of raw parameter values of a first plurality of modifiable parameters by a first probabilistic model and a first kernel;
executing a first test of a virtual driver of an autonomous system according to the first sample to generate a first evaluation result of a plurality of evaluation results;
updating the first probabilistic model according to the first evaluation result;
training the first kernel using the first evaluation result;
generating a second sample comprising a second plurality of raw parameter values of the first plurality of modifiable parameters by the first probabilistic model and the first kernel;
executing a second test of the virtual driver of the autonomous system according to the second sample to generate a second evaluation result of the plurality of evaluation results; and
presenting the plurality of evaluation results.

2. The method of claim 1, further comprising:
identifying that a number of iterations in a set of iterations comprising the first sample satisfies a threshold,
wherein training the first kernel is responsive to the number satisfying the threshold.

3. The method of claim 1, further comprising:
obtaining a specification of a first scenario comprising the first plurality of modifiable parameters; and
initializing the first probabilistic model and the first kernel based on the specification of the first scenario.

4. The method of claim 3, further comprising:
obtaining a second specification of a second scenario comprising a second plurality of modifiable parameters, the second plurality of modifiable parameters different from the first plurality of modifiable parameters;
initializing a second probabilistic model and a second kernel based on the specification of the second scenario; and
iteratively executing a plurality of tests using the second probabilistic model and the second kernel to generate a second plurality of evaluation results, wherein the second probabilistic model is updated, and the second kernel is trained independently of the first probabilistic model and the first kernel and using the second plurality of evaluation results.

5. The method of claim 1, wherein the first probabilistic model is a Gaussian model.

6. The method of claim 1, further comprising:
selecting the first sample from the first probabilistic model according to a level of uncertainty of sample regions in the first probabilistic model, wherein the probabilistic model is defined by the first kernel.

7. The method of claim 1, wherein the first kernel generates a similarity sample matrix relating a similarity to each pair of a plurality of samples, the similarity specifying a similarity between the pair, wherein the first sample is selected using the similarity sample matrix.

8. The method of claim 1, further comprising:
after training the first kernel, updating the first probabilistic model using the first kernel.

9. A system comprising:
at least one computer processor;
a first probabilistic model and a first kernel executing on the at least one computer processor and configured to perform first operations comprising:
generating a first sample comprising a first plurality of raw parameter values of a first plurality of modifiable parameters,
generating a second sample comprising a second plurality of raw parameter values of the first plurality of modifiable parameters;
a testing engine executing on the at least one computer processor and configured to perform second operations comprising:
executing a first test of a virtual driver of an autonomous system according to the first sample to generate a first evaluation result of a plurality of evaluation results,
executing a second test of the virtual driver of the autonomous system according to the second sample to generate a second evaluation result of the plurality of evaluation results;
a model training engine executing on the at least one computer processor and configured to perform third operations comprising:
updating the first probabilistic model according to the first evaluation result and prior to the second sample being generated;
a kernel training engine executing on the at least one computer processor and configured to perform fourth operations comprising:
training the first kernel using the first evaluation result; and
an evaluation engine executing on the at least one computer processor and configured to perform fifth operations comprising presenting the plurality of evaluation results.

10. The system of claim 9, wherein the fourth operations performed by the kernel training engine further comprises:
identifying that a number of iterations in a set of iterations comprising the first sample satisfies a threshold,
wherein training the first kernel is responsive to the number satisfying the threshold.

11. The system of claim 9, further comprising:
a scenario generator executing on the at least one computer processor and configured to perform sixth operations comprising:
obtaining a specification of a first scenario comprising the first plurality of modifiable parameters, and
initializing the first probabilistic model and the first kernel based on the specification of the first scenario.

12. The system of claim 11, wherein the sixth operations performed by the scenario generator further comprises:
obtaining a second specification of a second scenario comprising a second plurality of modifiable parameters, the second plurality of modifiable parameters different from the first plurality of modifiable parameters, and
initializing a second probabilistic model and a second kernel based on the specification of the second scenario, and
wherein the system is further configured to iteratively execute a plurality of tests using the second probabilistic model and the second kernel to generate a second plurality of evaluation results, wherein the second probabilistic model is updated and the second kernel is trained independently of the first probabilistic model and the first kernel and using the second plurality of evaluation results.

13. The system of claim 9, wherein the first probabilistic model is a Gaussian model.

14. The system of claim 9, wherein the first sample is selected from the first probabilistic model according to a level of uncertainty of sample regions in the first probabilistic model, wherein the first probabilistic model is defined by the first kernel.

15. The system of claim 9, further comprising:
a similarity sample matrix generated by the first kernel, the similarity sample matrix relating a similarity to each pair of a plurality of samples,
wherein the first sample is selected using the similarity sample matrix.

16. The system of claim 9, wherein the model training engine is configured to update the first probabilistic model using the first kernel after the first kernel is updated.

17. A non-transitory computer readable medium comprising computer readable program code for causing at least one computer processor to perform operations comprising:
generating a first sample comprising a first plurality of raw parameter values of a first plurality of modifiable parameters by a first probabilistic model and a first kernel;
executing a first test of a virtual driver of an autonomous system according to the first sample to generate a first evaluation result of a plurality of evaluation results;
updating the first probabilistic model according to the first evaluation result;
training the first kernel using the first evaluation result;
generating a second sample comprising a second plurality of raw parameter values of the first plurality of modifiable parameters by the first probabilistic model and the first kernel;
executing a second test of the virtual driver of the autonomous system according to the second sample to generate a second evaluation result of the plurality of evaluation results; and
presenting the plurality of evaluation results.

18. The non-transitory computer readable medium of claim 17, wherein the operations further comprise:
identifying that a number of iterations in a set of iterations comprising the first sample satisfies a threshold,
wherein training the first kernel is responsive to the number satisfying the threshold.

19. The non-transitory computer readable medium of claim 17, wherein the operations further comprise:
obtaining a specification of a first scenario comprising the first plurality of modifiable parameters; and
initializing the first probabilistic model and the first kernel based on the specification of the first scenario.

20. The non-transitory computer readable medium of claim 19, wherein the operations further comprise:
obtaining a second specification of a second scenario comprising a second plurality of modifiable parameters, the second plurality of modifiable parameters different from the first plurality of modifiable parameters;
initializing a second probabilistic model and a second kernel based on the specification of the second scenario; and
iteratively executing a plurality of tests using the second probabilistic model and the second kernel to generate a second plurality of evaluation results, wherein the second probabilistic model is updated, and the second kernel is trained independently of the first probabilistic model and the first kernel and using the second plurality of evaluation results.
